(19) United States
(12) Patent Application Publication
(10) Pub. No.: US 2025/0113460 A1
(43) Pub. Date: Apr. 3, 2025

(54) FOLDABLE THERMAL GROUND PLANES FOR ELECTRONIC DEVICES

(71) Applicant: Intel Corporation, Santa Clara, CA (US)

(72) Inventors: Jeff Ku, Taipei (TW); Smit Kapila, Bangalore (IN); Min Suet Lim, Gelugor (MY); Surya Pratap Mishra, Portland (IN); Kari Mansukoski, Hillsboro, OR (US); Shantanu D. Kulkarni, Hillsboro, OR (US)

(73) Assignee: Intel Corporation, Santa Clara, CA (US)

(21) Appl. No.: 18/979,203

(22) Filed: Dec. 12, 2024

(51) Int. Cl. H05K 7/20; G06F 1/20

(52) U.S. Cl. CPC H05K 7/20154; H05K 7/20336; G06F 1/203

(57) ABSTRACT

Systems, apparatus, articles of manufacture, and methods are disclosed for foldable thermal ground planes for electronic devices. An example an apparatus to cool an electronic device includes a first plate; a second plate; a plurality of first pillars extending between the first plate and the second plate, the plurality of first pillars having a first shape; a plurality of second pillars extending between the first plate and the second plate, the plurality of second pillars having a second shape, the second shape different than the first shape; and a hinge separating the apparatus into a first section and a second section, the plurality of second pillars in the hinge.

### BACKGROUND

Electronic devices include components that generate heat. Thermal solutions are implemented in the electronic devices to control the temperature of the components inside the electronic device.

### BRIEF DESCRIPTION OF THE DRAWINGS

FIG. 1 illustrates an example foldable thermal ground plane in an example electronic device constructed in accordance with teachings of this disclosure with example movable heat conductors of the foldable thermal ground plane in a first position.

FIG. 2 is an isolated view of the foldable thermal ground plane of FIG. 1.

FIG. 3 is a schematic cross-sectional view of the foldable thermal ground plane of FIG. 1.

FIG. 4 is a schematic cross-sectional view of an example hybrid of a foldable thermal ground plane with an example vapor chamber.

FIG. 5 illustrates the example foldable thermal ground plane in the example electronic device of FIG. 1 with the movable heat conductors of the foldable thermal ground plane in a second position.

FIG. 6 illustrates the example foldable thermal ground plane in the example electronic device of FIG. 1 with another one of the movable heat conductors of the foldable thermal ground plane in a second position.

FIG. 7 is a schematic cross-sectional view of the foldable thermal ground plane of FIG. 1 with an example seal.

FIG. 8 is an exploded view of an example foldable thermal ground plane and hermetic seal.

FIG. 9A illustrates a portion of an example electronic device with an example foldable thermal ground plane associated with an example backside thermal spreader with example movable heat conductors of the foldable thermal ground plane in first positions.

FIG. 9B illustrates the example foldable thermal ground plane of FIG. 9A with the example movable heat conductors of the foldable thermal ground plane in second positions.

FIG. 10 is a schematic cross-sectional view of the foldable thermal ground plane and electronic device of FIGS. 9A and 9B.

In general, the same reference numbers will be used throughout the drawing(s) and accompanying written description to refer to the same or like parts. The figures are not necessarily to scale. Instead, the thickness of the layers or regions may be enlarged in the drawings.

### DETAILED DESCRIPTION

Electronic devices, such as laptop computers, include thermal solutions to dissipate heat generated by components of the electronic device. Thermal solutions may include heat sinks, heat pipes, vapor chambers, thermal spreaders, fans, etc. In some electronic devices, there is a main thermal module, such as a large continuous vapor chamber, and multiple thermal spreaders that cover components such as processing units (e.g., a central processing unit (CPU), a graphics processing unit (GPU), a system on a chip (SOC), etc.), memories (e.g., a small outline dual in-line memory module (SODIMM), a low-power compression attached memory module (LPCAMM), a solid state drive (SDD), etc.), a flash memory, and/or other components.

Electronic devices also include fans that are separate from the vapor chambers. The fans include fan covers that are positioned over the fan blade. In some electronic devices, the fan covers are soldered to the vapor chamber. Soldering the fan cover, which is made of a high thermally conductive material such as aluminum or copper, to the vapor chamber increases the cooling capacity of the electronic device. For example, in a gaming laptop, the cooling capacity can be increased by about 5 to about 10 Watts when the fan cover is soldered to the vapor chamber. The cooling capacity is increased due to the increased surface area of the soldered fan cover and vapor chamber for heat exchange.

Service procedures may be performed on the electronic device during the lifetime of the electronic device. For example, more memory may be added to the electronic device, dust may be cleared from the fans, a battery may be replaced, etc. A vapor chamber and/or fan cover may need to be removed during such a service procedure to access these internal components of the electronic device. When a fan cover is soldered to the vapor chamber, the fan is accessed during a service procedure by disassembly of the soldered components rather than simply removal of the fan cover. There is less disassembly when the fan covers are kept separate from the vapor chambers. However, the separate fan covers have lower cooling capacity as discussed above. Similarly, thermal spreaders for memory components are typically separate from the main thermal module (e.g., main vapor chamber) to facilitate access to the memory components during a service procedure.

Disclosed herein are example foldable thermal ground planes that achieve both thermal cooling performance and improved serviceability. Example thermal ground planes disclosed herein include a fixed portion or fixed heat conductor and a flexible or movable portion or movable heat conductor that cover one or more heat sources and/or one or more modules. In examples disclosed herein, the movable heat conductors are coupled to the fixed heat conductors. Thus, in some examples, the movability indicates that the heat conductors are pivotable, where a portion of the movable heat conductors along a hinge that couples the movable heat conductor to the fixed heat conductor remain fixed. In some examples, the fixed heat conductor covers a heat source such as a CPU, a GPU, a video random access memory (VRAM), etc. In some examples, the movable heat conductor covers one or more components that may be serviced or serviced more frequently than other components and/or that may be replaced and/or added to such as, for example, SODIMM, LPCAMM, an expansion card (e.g., an M.2 module), fans, etc.

Example thermal ground planes disclosed herein include a soft hinge about which the thermal ground plane is foldable. In some examples, the soft hinge includes a plurality of parallel pillars that facilitate foldability of the thermal ground plane. In some examples, the thermal ground plane includes one or more stiffener plates that add rigidity to the thermal ground plane. In such examples, the stiffener plates are positioned over the fixed heat conductor of the thermal ground plane and/or over the movable heat conductor but not over the soft hinge.

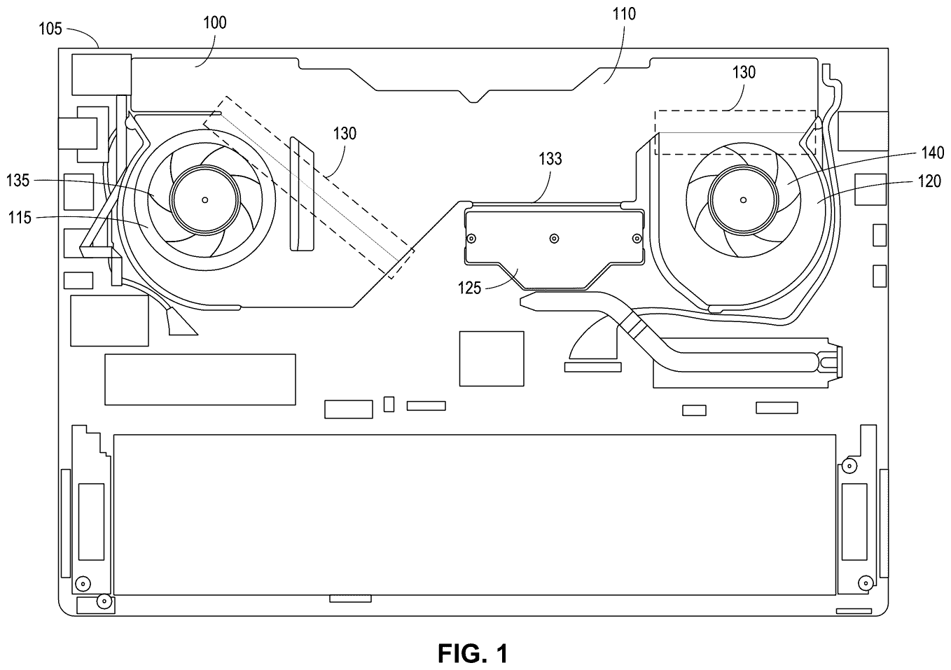

FIG. 1 illustrates an example foldable thermal ground plane 100 in an example electronic device 105. In the illustrated example, the electronic device 105 is a laptop computer. The base of the laptop computer is shown with the C-cover removed for purposes of illustration to expose interior components of the electronic device 105. Example foldable thermal ground planes disclosed herein may be incorporated into other types of electronic devices (e.g., tablets, mobile phones, etc.). In the illustrated example, the thermal ground plane 100 includes an example fixed heat conductor 110, an example first movable heat conductor 115, an example second movable heat conductor 120, and an example third movable heat conductor 125. In other examples, there are any other number of movable heat conductors such as one, two, four, etc. In some examples, the foldable thermal ground plane 100 has a thickness of about 0.15 millimeters or less.

The first movable heat conductor 115 and the second movable heat conductor 120 are rotatable or foldable about respective example first hinges 130. The third movable heat conductor 125 is rotatable or foldable about an example second hinge 133 The hinges 130, 133 may be referred to as soft hinges, hinge zones, fold zones, or folding areas. The hinges 130, 133 have an axis, which may be referred to as a hinge axis or fold axis, about which respective ones of the first movable heat conductor 115, the second movable heat conductor 120, and/or the third movable heat conductor 125 are rotatable or foldable. In the illustrated example of FIG. 1, the first movable heat conductor 115, the second movable heat conductor 120, and the third movable heat conductor 125 are in a first position in which the first movable heat conductor 115, the second movable heat conductor 120, and the third movable heat conductor 125 are folded down and respectively cover one or more corresponding electrical components. For example, the first movable heat conductor 115 covers a first fan 135, the second movable heat conductor 120 covers a second fan 140, and the third movable heat conductor 125 covers a memory and/or a memory module. The fixed heat conductor 110 covers additional electrical components such as, for example, a CPU.

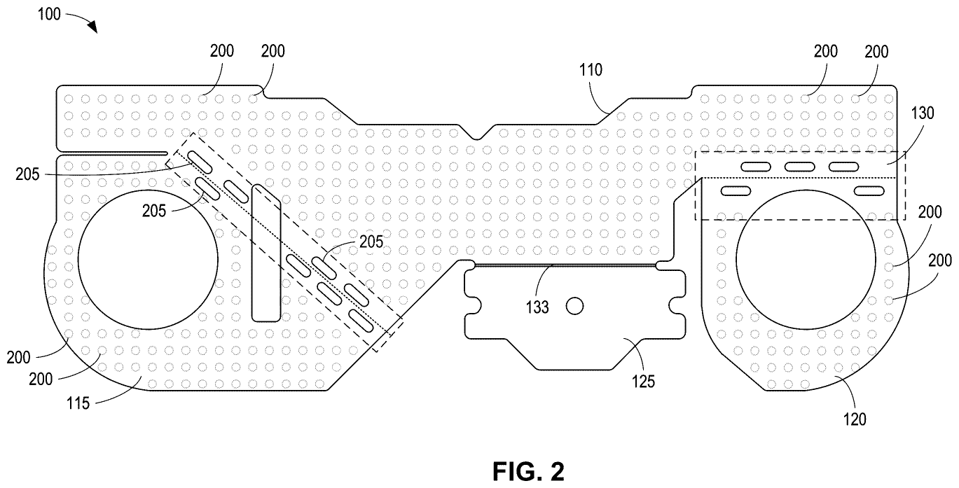

FIG. 2 is an isolated view of the foldable thermal ground plane 100. In this example, the thermal ground plane 100 forms a vapor chamber. The thermal ground plane includes a plurality of first pillars 200. In this example, the first pillars 200 have a circular cross-sectional shape. The first pillars 200 enable the exchange of evaporating vapors and condensation within the thermal ground plane 100. In some examples, the first pillars include wicks. The first pillars 200 are included throughout the fixed heat conductor 110. In the illustrated examples, the first pillars 200 also are included throughout the first movable heat conductor 115 and the second movable heat conductor 120. In some examples, the first movable heat conductor 115 and/or the second movable heat conductor 120 may not include any of the first pillars or may include only some of the first pillars 200. In the illustrated example, the third movable heat conductor 125 does not include the first pillars 200. However, in other examples, the third movable heat conductor 125 may include the first pillars 200. The first pillars 200 are not included in the hinges 130, 133. In some examples, the first pillars 200 include copper such as a stamped copper.

The hinges 130 of FIG. 2 include example second pillars 205. In some examples, the second pillars 205 can provide a cooling function similar to the first pillars 200. In the illustrated example, the second pillars 205 are shown in the hinge 130 between the first movable heat conductor 115 and the fixed heat conductor 110 and in the hinge 130 between the second movable heat conductor 120 and the fixed heat conductor 110. In some examples, there may be second pillars 205 in the hinge 133 between the third movable heat conductor 125 and the fixed heat conductor 110. In the illustrated example, the second pillars 205 have a cross-sectional shape that has a width and a length, the length greater than the width. In the illustrated example, the second pillars 205 have a cross-sectional shape that is an oval. Thus, the first pillars 200 have a first shape, and the second pillars 205 have a second shape, the second shape different than the first shape. In some examples, the second pillars 205 could also have a circular cross-sectional shape but with a diameter smaller than the diameter of the cross-section of the first pillars 200.

The shape and orientation of the second pillars 205 facilitates folding of the hinge 130. The lengths of the second pillars 205 align with and along the hinge axis. In the illustrated example, there are two rows of second pillars 205 that extend along the hinge 130. In other examples, there are any other numbers of rows such as one, three, four, etc. The number of rows of the second pillars 205 determines the width or bending radius of the transition or folding area of the hinge 130. More rows or second pillars 205 provide a softer hinge 130. There is a sharper bend of the hinge 130 with less rows of the second pillars 205. In some examples, the hinges 130, 133 are designed for a folding cycle count up to twenty times for each of the hinges 130, 133.

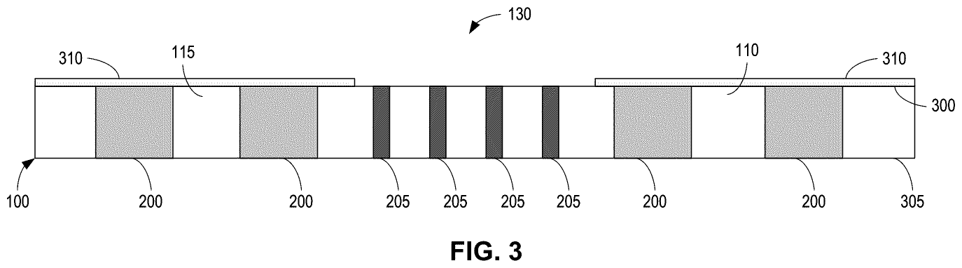

FIG. 3 is a schematic cross-sectional view of the foldable thermal ground plane 100. The foldable thermal ground plane 100 includes a first plate 300 and a second plate 305. In some examples, the first plate 300 and/or the second plate 305 are copper-cladded. In some examples, the first plate 300 and/or the second plate 305 are flexible copper-cladded polyimide sheets or other polymer. The first pillars 200 extend between the first plate 300 and the second plate 305 to form the vapor chamber. The second pillars 205 also extend between the first plate 300 and the second plate 305. The example of FIG. 3 shows four rows of second pillars 205. In some examples, a stiffener or stiffening plate 310 is included over the fixed heat conductor 110 and/or the first movable heat conductor 115 (and/or the second movable heat conductor 120 and/or the third movable heat conductor 125). In some examples, the stiffening plates 310 include copper, stainless steel, aluminum, other metal, plastic, and/or a combination of materials. Stiffening plates 310 are not included over the hinge 130. The stiffening plates 310 increase the rigidity of the foldable thermal ground plane 100 and prevent the foldable thermal ground plane 100 from being damaged under external pressure.

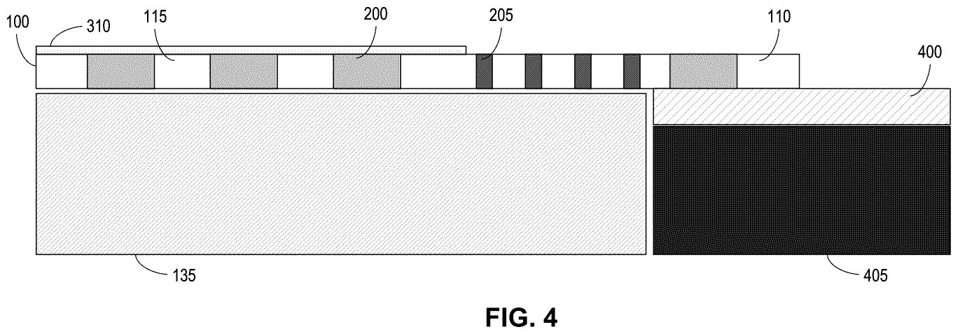

FIG. 4 is a schematic cross-sectional view of the foldable thermal ground plane 100 with an example second vapor chamber 400. FIG. 4 illustrates an example in which the stiffening plate 310 is only included over one of the movable heat conductors (e.g., the first movable heat conductor 115). The first movable heat conductor 115 covers the first fan, and the fixed heat conductor 110 covers the main heat generating components such as the CPU 405. The first movable heat conductor 115 is rotated about the hinge 130 to provide access to the first fan 135. In this example, the main heat sources are covered by the second vapor chamber 400, while the foldable thermal ground plane 100 covers heat sources and other components that require or benefit from easy access provided by the flexibility and/or movability. Thus, memories, fans, and/or other components can be accessed and serviced without dismantling the thermal solution (e.g., the second vapor chamber 400) over the CPU 405, but instead moving, pivoting, and/or holding a portion of the thermal ground plane 100.

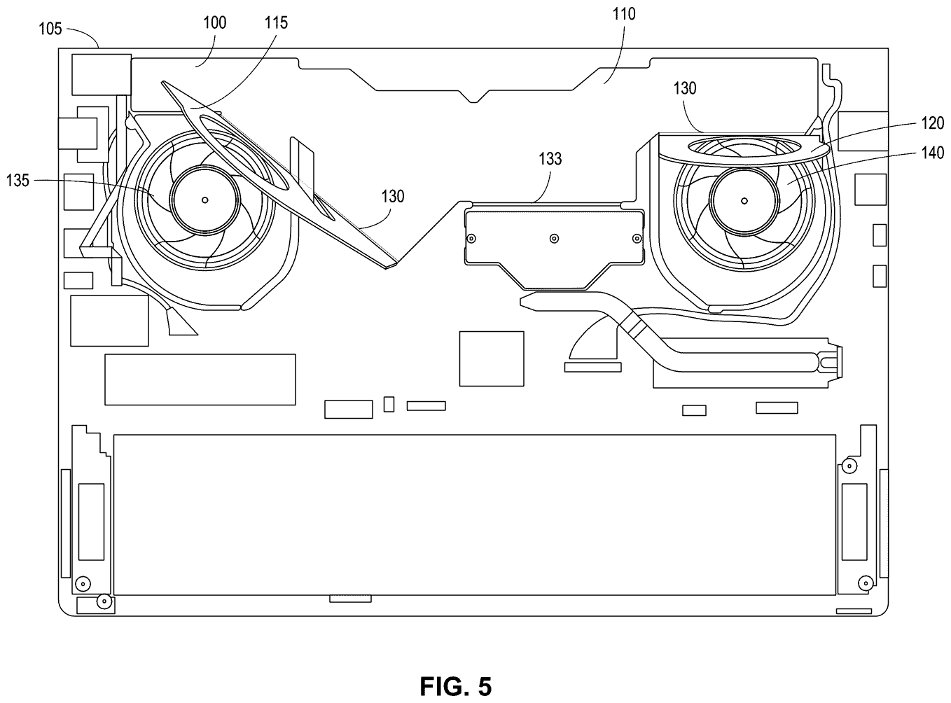

FIG. 5 illustrates the foldable thermal ground plane 100 of FIG. 1 with the first movable heat conductor 115 and the second movable heat conductor 120 in a second position after the first movable heat conductor 115 and the second movable heat conductor 120 have been rotated about respective hinges 130. When the first movable heat conductor 115 is in the second position of FIG. 5, the first fan 135 is easily accessible as the first movable heat conductor 115 has been moved away from covering the first fan 135. Similarly, when the second movable heat conductor 120 is in the second position of FIG. 5, the second fan 140 is easily accessible as the second movable heat conductor 120 has been moved away from covering the second fan 140. After the first fan 135 has been serviced, the first movable heat conductor 115 can be rotated about the hinge 130 to the first position shown in FIG. 1 where the first movable heat conductor 115 again covers the first fan 135 to perform heat dissipation. Similarly, after the second fan 140 has been serviced, the second movable heat conductor 120 can be rotated about the hinge 130 to the first position shown in FIG. 1 where the second movable heat conductor 120 again covers the second fan 140 to perform heat dissipation.

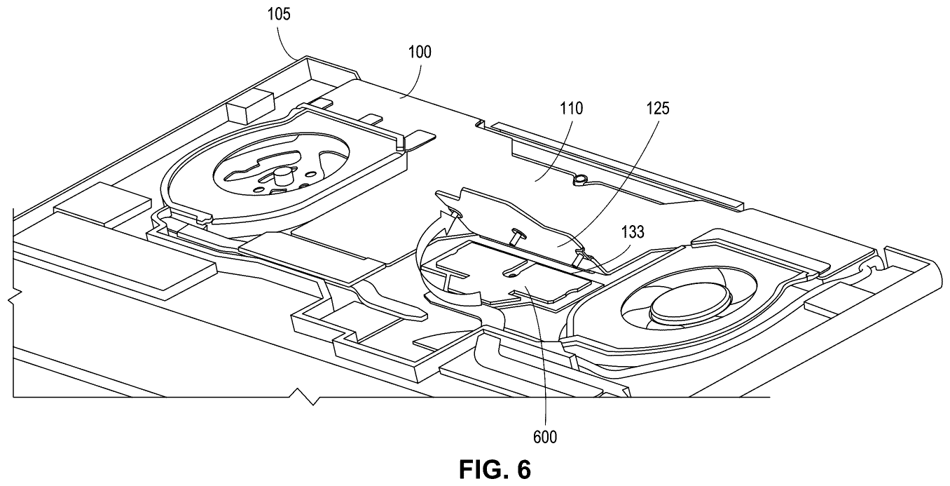

FIG. 6 illustrates the foldable thermal ground plane 100 with the third movable heat conductor 125 in a second position after the third movable heat conductor 125 has been rotated about the hinge 133. When the third movable heat conductor 125 is in the second position of FIG. 6, an example memory module 600 is accessible. After the memory module 600 has been serviced, the third movable heat conductor 125 can be rotated about the hinge 133 to the first position shown in FIG. 1.

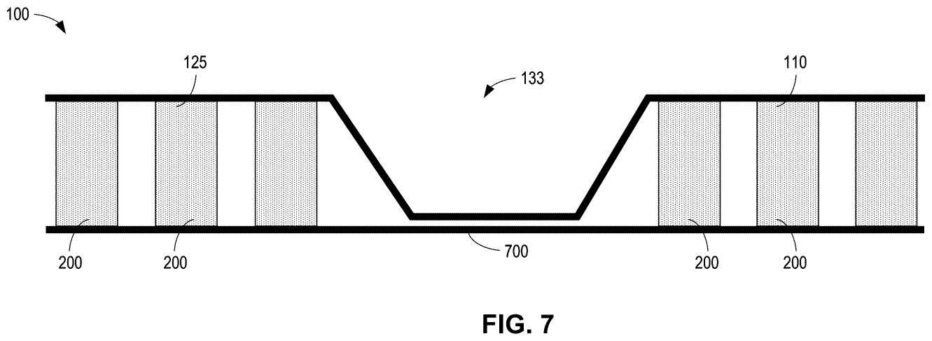

FIG. 7 is a schematic cross-sectional view of the foldable thermal ground plane 100 across the hinge 133. In this example, an example seal 700 is formed at the hinge 133. The seal 700 separates the third movable heat conductor 125 and the fixed heat conductor 110 of the foldable thermal ground plane 100. In some examples, the seal 700 is a hermetic seal. In some examples, the seal 700 is adjacent or within a hinge 130 that includes the second pillars 205.

Different components in the electronic device 105 generate different amounts of heat. For example, the CPU 405 generates more heat than the memory module 600. In some electronic devices, there is heat crosstalk between different heat generating devices. For example, a higher amount of heat generated from the CPU 405 could spread to the memory module 600. Heat crosstalk could be exacerbated if the different components share a thermal solution such as, for example, a heat spreader or vapor chamber, etc. The seal 700 separates the components covered by the fixed heat conductor 110 of the foldable thermal ground plane 100 from the components covered by the third movable heat conductor 125 of the foldable thermal ground plane 100. The seal 700 partitions the vapor within the separate sections of the foldable thermal ground plane 100. The seal 700 limits, reduces, prevents, and/or eliminates heat crosstalk between the components covered by the fixed heat conductor 110 and the components covered by the third movable heat conductor 125.

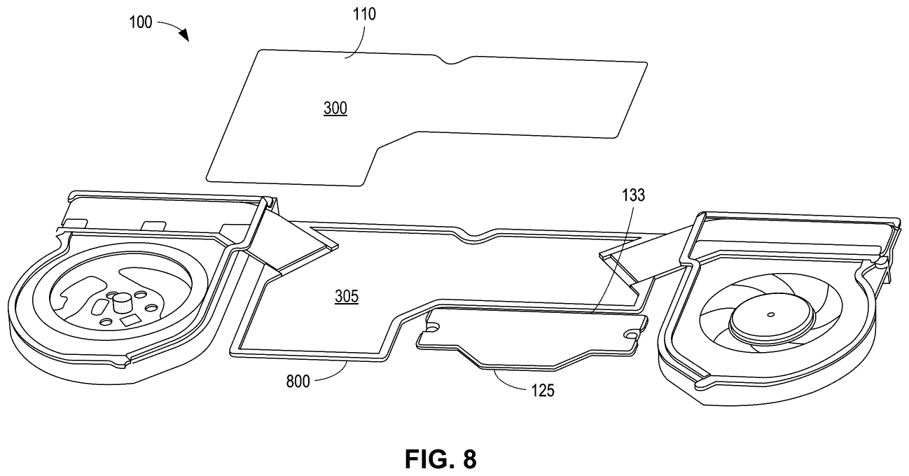

FIG. 8 is an exploded view of the foldable thermal ground plane 100 with an example frame 800 that is used to form the seal 700. In some examples, the frame 800 may be a copper frame. In the illustrated example, the frame 800 is positioned between the first plate 300 and the second plate 305 around the fixed heat conductor 110 of the foldable thermal ground plane 100.

Though the seal 700 is used to thermally separate the fixed heat conductor 110 of the foldable thermal ground plane 100 from the third movable heat conductor 125, the third movable heat conductor 125 is physically coupled to the fixed heat conductor 110 to facilitate manufacturing processes. In addition, there are less production costs than with conventional designs that manufacture an additional part. The fixed heat conductor 110 and the third movable heat conductor 125 may be made of similar or the same materials so the thermal conductivity of the third movable heat conductor 125 is similar to or the same as that of the fixed heat conductor 110 even though the third movable heat conductor 125 and the fixed heat conductor 110 are thermally separated.

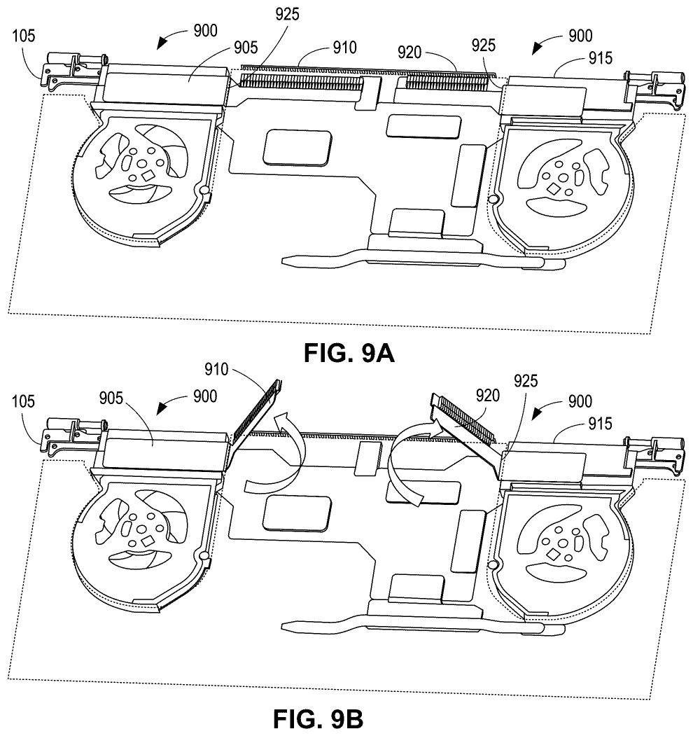

FIG. 9A illustrates another example foldable thermal ground plane 900. The foldable thermal ground plane 900 forms a backside thermal spreader for the electronic device 105. Backside thermal spreaders are for heat sources located on the bottom side of the main printed circuit board. In the illustrated example, the foldable thermal ground plane 900 includes a first fixed heat conductor 905, a first movable heat conductor 910, a second fixed heat conductor 915, and a second movable heat conductor 920. In FIG. 9A, the first movable heat conductor 910 and the second movable heat conductor 920 are in a first position, in which the first movable heat conductor 910 and the second movable heat conductor 920 are covering components coupled to the main printed circuit board.

The first movable heat conductor 905 and the second movable heat conductor 915 are foldable or rotatable about respective hinges 925. In some examples, the hinges 925 include the same structure(s) as the hinges 130 disclosed above. FIG. 9B illustrates the foldable thermal ground plane 900 with the first movable heat conductor 910 and the second movable heat conductor 920 in a second position. The first movable heat conductor 910 and the second movable heat conductor 920 are movable to the second position for serviceability and/or other access reasons. For example, the first movable heat conductor 910 and the second movable heat conductor 920 can be opened (i.e., rotated to the second position of FIG. 9B) to enable the printed circuit board to be assembled to the thermal module without the need for a thermal interface material. Additional thermal interface material increases thermal resistance and assembly costs.

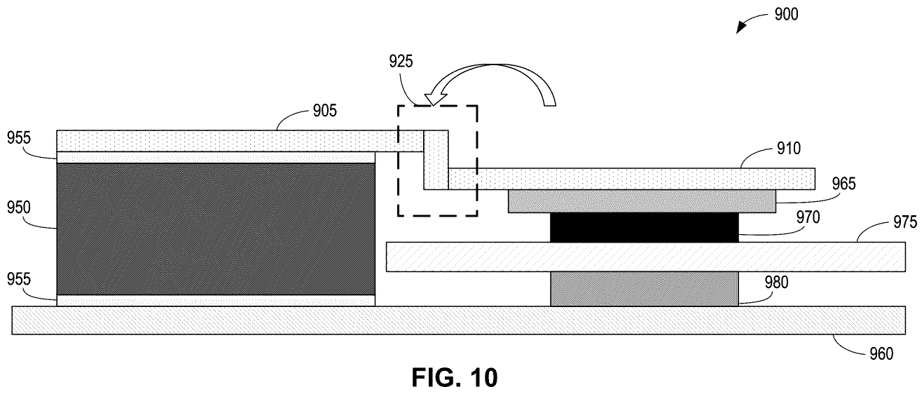

FIG. 10 is a schematic cross-sectional view of the foldable thermal ground plane 900 and electronic device 105 of FIGS. 9A and 9B. The first fixed heat conductor 905 is soldered directly to the backside of main thermal module heat exchangers 950. Likewise, the second fixed heat conductor 915 is soldered directly to the backside of main thermal module heat exchangers 950. Solder paste 955 is shown in FIG. 10 between the first fixed heat conductor 905 and the main thermal module heat exchanger 950. The main thermal module heat exchanger 950 is coupled to a main thermal module 960 via solder paste 955. The first movable heat conductor 910 of the foldable thermal ground plane 900 is removably positioned over other components including, for example, a gap pad or thermal gel 965, voltage regulating components 970, the main printed circuit board 975, and a system on a chip 980 (e.g., which carries the CPU 405). The first movable heat conductor 910 can be rotated about the hinge 925 to access the main printed circuit board 975 and components coupled thereto. In addition, the foldable thermal ground plane 900 enables efficient transfer of heat generated by the backside power components to the main heat exchanger 950 while reducing thermal resistance between the foldable thermal ground plane 900 and the main heat exchanger 950. Integrating a backside thermal spreader to the main thermal solution simplifies the assembling process and usage of thermal interface material, which is beneficial to thermal performance, cost, and sustainability.

Example thermal ground planes disclosed herein include fixed heat conductors and movable heat conductors that cover one or more different heat sources, modules, and/or other components to facilitate access to components of electronic devices without the need to dismantle the thermal solutions. Conventional rigid thermal solutions that require dismantling and/or removal of the rigid thermal solutions to service the electronic device have increased risk of damage to the printed circuit board or other components. Example thermal ground planes disclosed herein also increase the thermal capacity of the electronic device. In some examples, the thermal ground planes disclosed herein reduce junction temperature and/or processor (e.g., GPU, CPU, etc.) temperature by about four degrees Celsius. Thus, examples disclosed herein exhibit increased thermal conductivity.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

Example systems, apparatus, articles of manufacture, and methods are disclosed for foldable thermal ground planes for electronic devices. Example 1 includes an apparatus to cool an electronic device that includes a first plate; a second plate; a plurality of first pillars extending between the first plate and the second plate, the plurality of first pillars having a first shape; a plurality of second pillars extending between the first plate and the second plate, the plurality of second pillars having a second shape, the second shape different than the first shape; and a hinge separating the apparatus into a first section and a second section, the plurality of second pillars in the hinge.

Example 2 includes the apparatus of Example 1, wherein the first shape includes a circular cross-section and the second shape includes an oval cross-section.

Example 3 includes the apparatus of any of Examples 1 or 2, wherein the second shape includes a cross-section that has a width and a length, the length greater than the width.

Example 4 includes the apparatus of any of Examples 1-3, wherein the length is aligned along a fold axis of the hinge.

Example 5 includes the apparatus of any of Examples 1-4, wherein the first section is fixed and the second section is movable about a fold axis of the hinge.

Example 6 includes the apparatus of any of Examples 1-5, wherein the first plate and the second plate are parts of a vapor chamber.

Example 7 includes the apparatus of any of Examples 1-6, including a first stiffener coupled to the first plate in the first section and a second stiffener coupled to the first plate in the second section.

Example 8 includes the apparatus of any of Examples 1-7, including a seal adjacent the plurality of second pillars.

Example 9 includes an electronic device that includes a heat exchanger including: a fixed heat conductor; a movable heat conductor; and a hinge joining the fixed heat conductor and the movable heat conductor, the hinge having a hinge axis, the movable heat conductor rotatable about the hinge axis; a first electrical component beneath the fixed heat conductor; and a second electrical component beneath the movable heat conductor, the movable heat conductor to be rotated about the hinge axis to facilitate access to the second electrical component.

Example 10 includes the electronic device of Example 9, wherein the heat exchanger includes: a plurality of first pillars in the fixed heat conductor and the movable heat conductor, the plurality of first pillars having a first shape; and a plurality of second pillars in the hinge, the plurality of second pillars having a second shape, the second shape different than the first shape.

Example 11 includes the electronic device of any of Examples 9 or 10, wherein the first shape includes a circular cross-section and the second shape includes an oval cross-section.

Example 12 includes the electronic device of any of Examples 9-11, wherein the second shape includes a cross-section that has a width and a length, the length greater than the width, and the length aligned along the hinge axis.

Example 13 includes the electronic device of any of Examples 9-12, wherein the plurality of second pillars are arranged in a plurality of rows.

Example 14 includes the electronic device of any of Examples 9-13, wherein the rows extend along the hinge axis.

Example 15 includes the electronic device of any of Examples 9-14, wherein the heat exchanger is a vapor chamber.

Example 16 includes the electronic device of any of Examples 9-15, including a stiffening plate coupled to at least one of the fixed heat conductor or the movable heat conductor.

Example 17 includes the electronic device of any of Examples 9-16, wherein the first electrical component includes processor circuitry and the second electrical component includes a fan.

Example 18 includes the electronic device of any of Examples 9-17, wherein the first electrical component is to generate a first amount of heat and the second electrical component is to generate a second amount of heat, the second amount less than the first amount.

Example 19 includes the electronic device of any of Examples 9-18, wherein the heat exchanger includes a seal between the fixed heat conductor and the movable heat conductor.

Example 20 includes the electronic device of any of Examples 9-19, including a hermetic seal between the fixed heat conductor and the movable heat conductor.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus to cool an electronic device, the apparatus comprising:
a first plate;
a second plate;
a plurality of first pillars extending between the first plate and the second plate, the plurality of first pillars having a first shape;
a plurality of second pillars extending between the first plate and the second plate, the plurality of second pillars having a second shape, the second shape different than the first shape; and
a hinge separating the apparatus into a first section and a second section, the plurality of second pillars in the hinge.

2. The apparatus of claim 1, wherein the first shape includes a circular cross-section and the second shape includes an oval cross-section.

3. The apparatus of claim 1, wherein the second shape includes a cross-section that has a width and a length, the length greater than the width.

4. The apparatus of claim 3, wherein the length is aligned along a fold axis of the hinge.

5. The apparatus of claim 1, wherein the first section is fixed and the second section is movable about a fold axis of the hinge.

6. The apparatus of claim 1, wherein the first plate and the second plate are parts of a vapor chamber.

7. The apparatus of claim 1, including a first stiffener coupled to the first plate in the first section and a second stiffener coupled to the first plate in the second section.

8. The apparatus of claim 1, including a seal adjacent the plurality of second pillars.

9. An electronic device comprising:
a heat exchanger including:
a fixed heat conductor;
a movable heat conductor; and
a hinge joining the fixed heat conductor and the movable heat conductor, the hinge having a hinge axis, the movable heat conductor rotatable about the hinge axis;
a first electrical component beneath the fixed heat conductor; and
a second electrical component beneath the movable heat conductor, the movable heat conductor to be rotated about the hinge axis to facilitate access to the second electrical component.

10. The electronic device of claim 9, wherein the heat exchanger includes:
a plurality of first pillars in the fixed heat conductor and the movable heat conductor, the plurality of first pillars having a first shape; and
a plurality of second pillars in the hinge, the plurality of second pillars having a second shape, the second shape different than the first shape.

11. The electronic device of claim 10, wherein the first shape includes a circular cross-section and the second shape includes an oval cross-section.

12. The electronic device of claim 10, wherein the second shape includes a cross-section that has a width and a length, the length greater than the width, and the length aligned along the hinge axis.

13. The electronic device of claim 10, wherein the plurality of second pillars are arranged in a plurality of rows.

14. The electronic device of claim 13, wherein the rows extend along the hinge axis.

15. The electronic device of claim 9, wherein the heat exchanger is a vapor chamber.

16. The electronic device of claim 9, including a stiffening plate coupled to at least one of the fixed heat conductor or the movable heat conductor.

17. The electronic device of claim 9, wherein the first electrical component includes processor circuitry and the second electrical component includes a fan.

18. The electronic device of claim 9, wherein the first electrical component is to generate a first amount of heat and the second electrical component is to generate a second amount of heat, the second amount less than the first amount.

19. The electronic device of claim 18, wherein the heat exchanger includes a seal between the fixed heat conductor and the movable heat conductor.

20. The electronic device of claim 9, including a hermetic seal between the fixed heat conductor and the movable heat conductor.
